(19) United States
(12) Patent Application Publication
(10) Pub. No.: US 2004/0088124 A1
(43) Pub. Date: May 6, 2004

(54) Method and device for measuring an electric signal power

(76) Inventors: Laure Van Schendel, Paris (FR); Pierre Force, Nezel (FR); Roland Stoffel, Elancourt (FR)

Correspondence Address: Dan C Hu, Trop Pruner & Hu, Suite 100, 8554 Katy Freeway, Houston, TX, 77024, US

(21) Appl. No.: 10/333,097

(22) PCT Filed: Jun. 29, 2001
(86) PCT No.: PCT/FR01/02090

(30) Foreign Application Priority Data
Jul. 17, 2000 (FR) 00 09314

(51) Int. Cl. G06F 19/00; G01R 21/00

(52) U.S. Cl. 702/60

(57) ABSTRACT

The invention concerns a method and a device for measuring the power of an electric signal (S) enabling to: (a) produce a series of successive samples (Sn) of the signal (S); (b) producing a sequence of successive values (Pn) of the signal (S) instantaneous power, each of said values being obtained from the value of a respective sample of the sequence of successive values (Sn) of the signal (S); (c) producing N sequences of successive values (Pjn) of the average power of the signal (S) on respectively N time windows with increasing respective widths, where N is an integer such that N≧2, from the values of die sequence of successive values (Pn) of the signal (S) instantaneous power.

The present invention relates to a method and a device for measuring the power of an electric signal.

It finds applications in telecommunications receivers, such as may be found for example in the fixed equipment (base stations) or the mobile equipment (portable terminals) of radiocommunication systems. In such an application, the signal considered is for example a radiofrequency signal such as a phase-modulated and/or amplitude-modulated carrier, or a signal resulting from the transposition of such a signal to an intermediate frequency.

It is frequent to have to measure the power of such a signal so as to adjust the gain of a stage of the reception chain, for example by means of a variable-gain amplifier and an automatic gain control device, so as to escape the consequences of the variations in the power of the radioelectric signal received via an antenna of the receiver on the downstream part of the reception chain. Specifically, the power of a radiofrequency signal received on an antenna varies over time. These variations may be due to the appearance or the disappearance of obstacles between the transmitter and the receiver, to the appearance or the disappearance of other signals in the frequency band occupied by the signal, or to “fading” when there is a relative motion of the receiver with respect to the transmitter.

Fading is considerable when the Doppler frequency of fₒ×v/c is considerable, where fo is the central frequency of the signal spectrum, v is the relative speed of the receiver with respect to the transmitter and c is the speed of light. It is noted that when a signal is situated in a “fading hole” its power may become very small. The decrease in the power of the signal received in a fading hole is of short duration. In fact, the shorter the duration of the “fading hole”, the smaller the power of the signal in the “fading hole”.

The gain of the amplifier is conventionally controlled by the automatic gain control device, as a function of measurements of the power of the signal which are carried out at regular time intervals. However, when dealing with a measurement of the instantaneous power of the signal received, the small variations in this power due to the fluctuation of the power of the signal received give rise to changes in the gain of the amplifier which may prove to be inopportune in the sense that they could possibly destabilize the reception chain.

So as not to be too sensitive to the fluctuations, due to “fading”, in the power of the signal received, the automatic gain control device can be controlled as a function of a measurement of the received signal's mean power calculated over a specified time window. The larger this time window, the less sensitive is the device to the fluctuations in the power of the signal received. This makes it possible to avoid inopportune changes in the gain of the amplifier.

From another standpoint, the measurement of the mean power of the signal is then available only after the expiry of this time window. This lag may be penalizing in certain cases, in particular on switching on the receiver. Specifically, to the extent that it causes a delay in the adjusting of the reception chain.

An object of the invention is to propose a simple and reliable method of measuring the power of an electric signal making it possible to obtain, continuously, various measurements of the power of an electric signal.

Specifically, the invention proposes a method of measuring the power of an electric signal comprising the steps consisting in:

a) producing a series of successive samples of the signal;

b) producing a series of successive values of the instantaneous power of the signal, from the values of the series of successive samples of the signal;

c) producing N series of successive values of the mean power of the signal over respectively N time windows of respective increasing widths, where N is an integer such that N≧2, from the values of the series of values of the instantaneous power of the signal.

The invention also proposes a device for measuring the power of an electric signal comprising:

a) means for producing a series of successive samples of the signal;

b) means for producing a series of successive values of the instantaneous power of the signal, each of these values being obtained from the value of a respective sample of the series of successive samples of the signal;

c) means for producing N series of successive values of the mean power of the signal over respectively N time windows of respective increasing widths, where N is an integer such that N≧2, from the values of the series of successive values of the instantaneous power of the signal.

The method and device therefore make it possible to obtain values of the instantaneous power of the electric signal and values of its mean power, calculated over various time windows.

The invention further proposes a radiofrequency radiocommunication receiver incorporating a device as defined hereinabove.

Other characteristics and advantages of the invention will become further apparent on reading the description which follows. The latter is purely illustrative and should be read in conjunction with the appended figures, wherein:

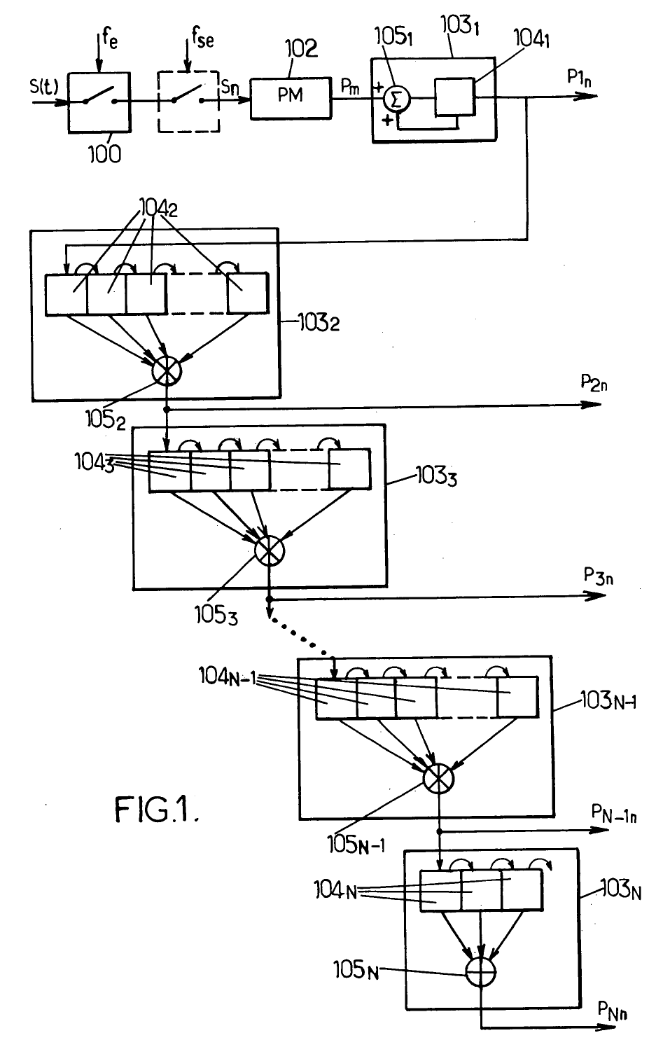

FIG. 1 is the diagram of a device according to the invention;

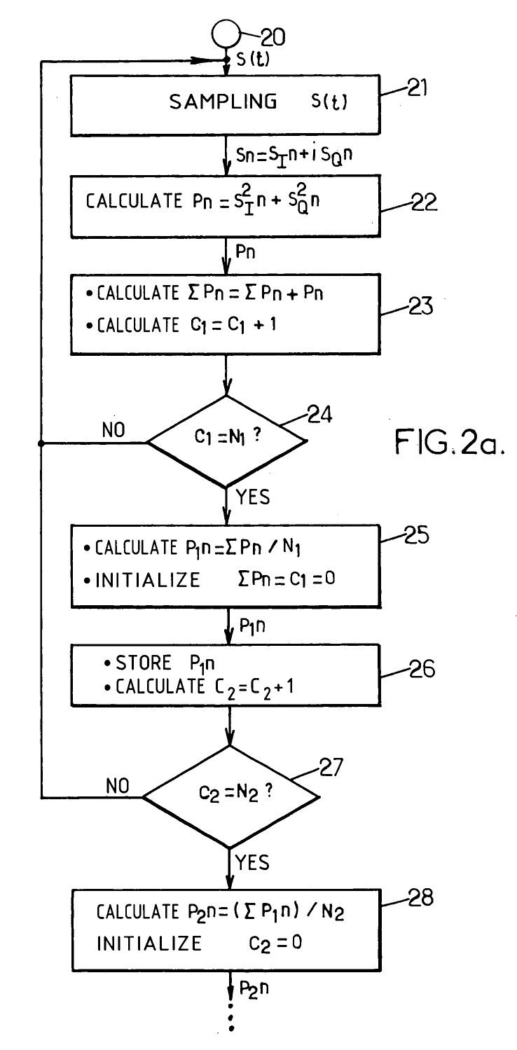

FIG. 2 is a flowchart showing the steps of a method according to the invention;

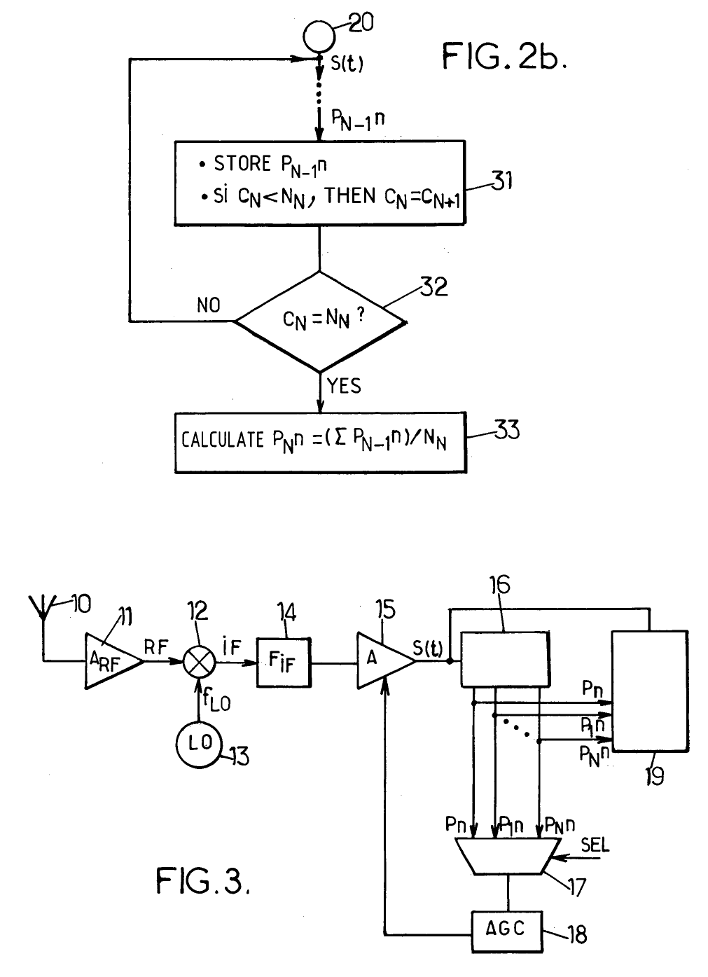

FIG. 3 is the diagram of a radiofrequency receiver incorporating a device according to the invention;

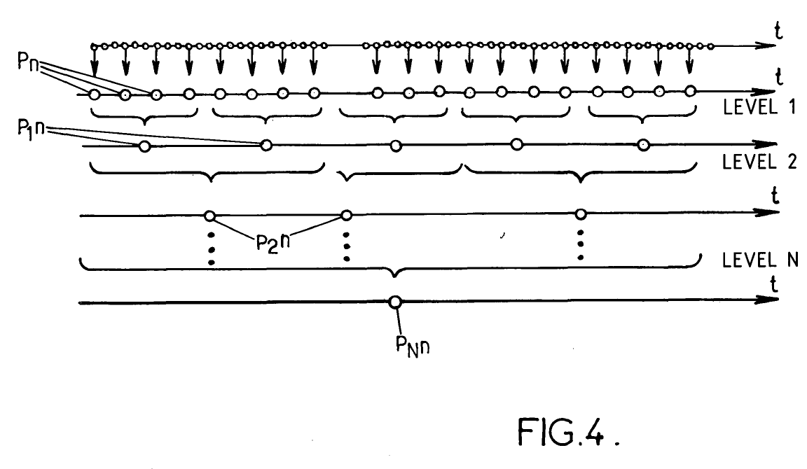

FIG. 4 show timing diagrams showing various series of values of mean power which are produced according to the invention.

Represented in FIG. 1 is the diagram of a device according to the invention for measuring the power of any electric signal S. This signal is a function of time. The electric signal S(t) is for example a phase-modulated and/or amplitude-modulated radiofrequency carrier.

A quantization module 100 produces quantized numerical values of the signal S(t) with a sampling frequency fe complying with Shannon's condition. Optionally, a subsamplingis carried out by a subsampling module 101, represented dashed in FIG. 1, at a subsampling frequency of fₛₑ which is a submultiple of the sampling frequency fₑ. In one example, fₛₑ=fₑ/125, so that one sample in 125 is sent by the module 101 from the samples produced by the module 100. In what follows, the series of signal S(t) values produced by the module 100 and, as the case may be, the module 101, is denoted Sn. These values are for example coded on p bits, where p is an integer.

The device further comprises a module 102 for calculating instantaneous power receiving as input the series of values Sn. This circuit has the function of producing a series of values Pn of the instantaneous power of the signal S(t), from the series of values Sn. The values Sn being writable in the form of an imaginary number Sn=S_{I}n+i. S_{Q}n, where S_{I}n and S_{Q}n are real numbers and where i²=−1, the values Pn are obtained successively from the successive values Sn by performing for each the calculation Pn=S²_{I}n+S²_{Q}n. The values Pn are therefore coded on 2 p bits.

The device further comprises, according to the invention, N mean power calculation modules arranged in cascade, where N is an integer. Each of these modules, referenced 103₁ to 103_{N} in FIG. 1, allows the continuous production of the series of values P₁n to P_{N}n respectively of the mean power of the signal S(t), calculated over increasing respective time windows directly or indirectly from the values Pn of the series of values of the instantaneous power of the signal S(t). The modules 103₁ to 103_{N} are in what follows called modules for calculating mean power of level 1 to N respectively. These are synchronous modules.

The module 103₁ for calculating mean power of level 1 comprises a memory register 104₁, as well as a counter C₁ counting up to N₁, where N₁ is an integer such that N₁≧2, (not represented) and means for resetting to zero the register 104₁ and the counter C₁ (also not represented). It further comprises means of addition 105₁, a first input of which is coupled to the output of the circuit 102 for calculating instantaneous power so as to receive the values Pn of the instantaneous power of the signal S(t), a second, input of which is coupled to an output of the register 104₁ so as to receive the current value stored in this register, and the output of which is coupled to the input of said register 104₁. With each reception of a new value Pn, the means of addition 105₁ produce a value equal to the sum of said value Pn and of said current value stored in the register 104₁ this sum value being stored in the register 104₁ in place of said current value. Stated otherwise, the hereinabove means of the module 103₁ form an accumulator register. Such a register is of very simple structure and requires little memory space, since the register 104₁ must have a length enabling it to store the result of the addition of N1 words of 2 p bits, that is equal to 2p+N1 only.

The module 103₁ for calculating the mean power of level 1 outputs a series of values Pn which are obtained successively for example by averaging over N₁ successive values Pn of the instantaneous power of the signal S(t) . Preferably, this is an arithmetic mean, which is the simplest to implement since it requires just one complex step of division by N₁. Accordingly, the counter is incremented by one unit with each reception of a new value Pn and corresponding updating of the value stored in the register 104₁. When the counter reaches the value N₁, the value stored in the register 104₁ is divided by N1 to yield an arithmetic mean of the last N₁ successive values Pn of the instantaneous power of the signal S(t) which were received at the input of the module 103₁. A value P₁n of the mean power of level 1 of the signal S(t) is thus produced. Moreover, the value of the counter C₁ and the value stored in the register 104₁ are reset to zero. Preferably, the integer N₁ is an integer power of 2, that is there exists a nonzero integer k₁ such that N₁=2^{k}1. This makes it possible to simplify the step of division by N₁ since it is then sufficient to eliminate the N₁ least significant bits of the value stored in the register 104₁ to produce the value P₁n.

Each circuit 103ⱼ for calculating the mean power of level j, where j is an index such that 2≦j≦N, produces a j-th series of values Pⱼn of the mean power of level j of the signal S(t) from Nⱼ values of the j-1-th series of values Pⱼ₋₁n of the mean power of level j-1 of the signal S(t), where Nⱼ is an integer such that Nⱼ≧2. It is necessary to distinguish between the last module 103_{N} (for which j=N) and the other modules 103ⱼ (for which 2≦j≦N)

For the values of j such that 2≦j≦N, the values of the j-th series of values Pjn of the mean power of the signal S(t) are obtained successively by averaging over successive Nⱼ-tuples of successive values of the j-1-th series of values Pⱼ₋₁n of the mean power of level j-1 (immediately lower level) of the signal S(t). Preferably, this is an arithmetic mean, which is the simplest to implement since it requires few complex calculations.

Accordingly, each module 103ⱼ for calculating the mean power of level j can have the same structure as the module 103₁ for calculating the mean power of level 1 described hereinabove, with a counter Cⱼ counting up to Nⱼ.

Nevertheless, in a preferred exemplary embodiment, each module 103ⱼ for calculating the mean power of level j comprises, in place of the memory register 104₁ of the module 103₁, a shift register 104ⱼ of length Nⱼ, that is comprising Nⱼ elementary registers in series, as well as a counter Cⱼ (not represented) counting up to Nⱼ and means (also not represented) for resetting to zero the counter Cⱼ and optionally the register 104ⱼ. It further comprises means of addition 105ⱼ with Nⱼ inputs which are linked respectively to the. outputs the Nⱼ elementary registers 104ⱼ so as to receive the Nⱼ values stored in the shift register 104ⱼ. The input of each module 103ⱼ is coupled to the output of the module 103ⱼ₋₁ so as to receive the values Pⱼ₋₁n and its output is coupled to the input of the module 103ⱼ₊₁ so as to send it the values Pⱼn. Each time a value Pⱼ₋₁n is input into the shift register 104ⱼ, the counter Cⱼ is incremented by one unit. When Nⱼ values Pⱼ₋₁n of the mean power of level j-1 (immediately lower level) have been input into the shift register 104ⱼ, that is when Cⱼ =Nⱼ these Nⱼ values are added together in the adder 105ⱼ. The sum obtained is then divided by Nⱼ to produce a value Pⱼn of the mean power of level j of the signal S(t) . Moreover, the shift register 104ⱼ can be emptied of the values which it contains, by virtue of the abovementioned means for resetting to zero. Preferably, each integer Nⱼ is an integer power of 2, that is there exists an integer kⱼ such that Nⱼ=2^{kj}. This simplifies the step of division by Nⱼ, as has been set forth previously.

The structure of the modules 103ⱼ for calculating mean power of level j for 2≦j≦N thus enables them to keep in memory, in the shift register 104ⱼ, the previous values of the mean power of level j−1. These may thus be used at any instant, depending on the requirements of the application.

As a variant, the means for producing the values of the N-th series of values Pⱼn of the mean power of level j of the signal S(t) and which consist of the modules 103_{N}, can operate successively by taking a sliding average over the Nⱼ-tuple of the last Nⱼ successive values of the j-1-th series of values Pⱼ₋₁n of the mean power of the signal S(t). The advantage resides in the fact that these values of sliding average are obtained more quickly.

Let us now see the particular case of the last module 103_{N}. The values of the last series of values P_{N}n of the mean power of level N of the signal S(t) are obtained successively by taking a sliding average over the successive K_{N}-tuples of the last N_{N} values of the N-1-th series of values P_{N-1}n of the mean power of level N-1 (immediately lower level) of the signal S(t).

Accordingly, the module 103_{N} for calculating the mean power of level N can have the same structure as the module 103₁ for calculating the mean power of level 1 described earlier, with a counter C_{N} counting up to N_{N}, but which is not reset to zero after the calculation of each value P_{N}n.

Nevertheless, in a preferred exemplary embodiment, the module 103_{N} for calculating the mean power of level N of the signal S(t) comprises a shift register 104_{N} of length N_{N}, that is comprising N_{N} elementary registers in series, and an adder 105_{N} with N_{N} inputs for receiving respectively the N_{N} values stored in the shift register 104_{N}, where N_{N} is an integer. The input of the module 103_{N} is coupled to the output of the module 103_{N-1} for calculating the mean power of level N-1 (immediately lower level). With each input of a new value P_{N-1}n of the mean power of level N-1 of the signal S(t) into the shift register 104_{N}, the values which are stored therein are shifted so that the oldest value P_{N-1}n stored in the shift register 104_{N} is lost. Moreover, a sum of the N_{N} values newly stored in this register is calculated by virtue of the means of addition 105_{N}. The value thus obtained is divided by N_{N} to produce the value P_{N}n of the mean power of level N of the signal S(t), according to (preferably) an arithmetic mean. Preferably, the integer N_{N} is an integer power of 2, that is there exists an integer k_{N} such that N_{N}=2^{k}N, this simplifying the step of division by N_{N} as was set forth previously. This calculation produces a value P_{N}n of the mean power of level N of the signal S(t).

In one example, the values of the series P₁n to P_{N}n are all coded on 2 p bits. However, this is not compulsory. In particular, certain bits coding a value which is produced of mean power of specified level may be truncated or appended, so as to take account of the dynamic swing of the signal which may be less than the input dynamic swing in power of the quantization module 100, and/or to accommodate the format of the data at the inputs of the electronic circuits downstream.

The modules 104₁ to 104_{N} for calculating the mean power of level 1 to N respectively of the input signal are for example embodied in the form of hardware and/or software modules, for example in a microcontroller, an ASIC circuit, a DSP circuit, an FPGA circuit, or the like.

In the diagram of FIG. 4, the small circles on the first horizontal axis (the one at the top) represent the samples of the signal S(t) at the output of the quantization module 100. The small circles on the second horizontal axis represent, with fₛₑ=fₑ/3, the values Pn of the instantaneous power of the signal S(t). Likewise, on each of the other horizontal axes underneath, the small circles respectively represent the values of the series of values P₁n to P_{N}n of the mean power of level 1 to N respectively of the signal S(t).

As will have been understood, the successive values Pn of the instantaneous power of the signal S(t) which are delivered by the circuit 102 bring about the cascaded generation of the series of values P₁n to P_{N}n of the mean power of level 1 to N respectively of the signal S(t). Thus, a value P₁n of the mean power of level 1 is a value of the signal S(t) mean power calculated over a time window of width equal to N₁ times an elementary duration separating two successive values Pn of the instantaneous power of the signal S(t). This elementary duration is equal to 1/fe×fse. Likewise, a value P₂n of fe x fse the mean power of level 2 is a value of the signal S(t) mean power calculated over a time window of width equal to N₁×N₂ times this elementary duration. Expressed in a general manner, this signifies that a value Pⱼn of the mean power of level j of the signal S(t) is a value of the signal S mean power calculated over a time window of width equal to N₁×N₂× . . . ×Nⱼ₋₁×Nⱼ times the duration separating two consecutive values Pn of the instantaneous power of the signal S(t). These time windows are therefore of respective increasing width.

Thus, the more the level j of the mean power of the signal S(t) increases, the more the small variations in the values of the signal S(t) are masked in the value Pjn of this mean power of level j. Nevertheless, the smaller the level of this mean power, the more quickly are the values Pjn of the mean power of the signal S(t) available after the device has been switched on. By placing in parallel N series of values of the mean power of level 1 to N of the signal S(t), together with a series of values Pn of the instantaneous power of the signal S(t), it is possible to improve the processing capability in a radio receiver incorporating the power measurement device. In one example, N is equal to five, N₁, N₄ and N₅ are equal to eight, and N₂ and N₃ are equal to two.

Represented in FIG. 2a and in FIG. 2b are flowcharts showing the steps of a method for measuring the power of an electric signal according to the invention. For the sake of clarity, the flowchart has been separated into two figures.

In FIG. 2a, a step 20 the so-called device initialization step consists in initializing the value of the counters Cⱼ of the modules 103ⱼ, so that for any j lying between 1 and N, Cⱼ=0. Likewise, the value ΣPn contained in the register 104₁ of the module 103₁ is initialized to zero.

In a step 21, the signal S(t) is sampled so as to produce a sample Sn. This sample can be written in the aforesaid form Sn=S_{I}n+i.S_{Q}n. In a step 22, a value Pn of the instantaneous power of the signal S(t) is then calculated as a function of this sample Sn. This value Pn is given by Pn=S_{I}n²+S²_{Q}n.

The following steps 23 to 25 are intended to produce a value P₁n of the mean power of level 1 of the signal S(t) , from N₁ successive values Pn of the instantaneous power of the signal S(t). In step 23, the value ΣPn stored in the register 104₁ of the module 103₁ is increased by the value Pₙ produced in step 22. Stated otherwise, the addition ΣPn=ΣPn+Pn is carried out. Moreover, the counter C₁ of the module 103₁ is incremented by one unit so that C₁=C₁+1. In step 24, the value of the counter C₁ is compared with the value N₁. If C₁=N₁ we go to step 25. Otherwise, we return to step 21 to produce the next sample Sn of the signal S(t). In step 25, the value P₁n is calculated by dividing the value ΣPn stored in the register 104₁ of the module 103₁ by the value N₁. Stated otherwise, the calculation P1n=ΣPn/N₁ is carried out. Moreover, the value ΣPn and the value C₁ are then initialized, so that ΣPn=C₁=0. The value P₁n is transmitted at the input of the module 103₂ for calculating the mean power of level 2 of the signal S(t).

The following steps 26 to 28 are intended to produce a value P₂n of the mean power of level 2 of the signal S(t) , from N₂ successive values P₁n of the first series of values P₁n of the mean power of the signal of level 1 of the signal S(t) . In step 26, the value P₁n is stored in the shift register 104₂ of the module 103₂. Moreover, the value of the counter C₂ is incremented by one unit, so that C₂=C₂+1. In step 27, the value of the counter C₂ is then compared with the value N₂. If C₂=N₂ we go to step 28. Otherwise, we return to step 21 to calculate a new sample Sn of the signal S(t), and we repeat all the steps 21 to 27. In step 28, that is when N₂ successive values P₁n have been stored successively in the register 104₂, the mean of these values is calculated so as to obtain a value P₂n of the second series of value of the mean power of the signal S(t). Stated otherwise, P₂n=(ΣP₁n)/N₂ is calculated. Moreover, the value of the counter C₂ is initialized, so that C₂=0. The value P₂n is transmitted at the input of the module 104₃ for calculating the mean power of level 3 of the signal S(t).

Steps (not represented) comparable to steps 26 to 28 are then performed to generate the values Pⱼn of the j-ths series of values of the mean power of the signal S(t), for every j lying between 3 and N-1.

Regarding the values of the N-th series of values P_{N}n of the mean power of level N of the signal S(t), reference is now made to the flowchart of FIG. 2b. In this figure has been represented the initialization step 20 of the method according to the invention, which can also be seen in FIG. 2a. The values P_{N-1}n of the N-1-th series of value of the mean power of the signal S(t) are produced by steps identical to the aforesaid steps 26 to 28. In a step 31, the value P_{N-1}n is stored in the register 104_{N} of the module 103_{N}. Moreover, if the value of the counter C_{N} (which was initialized during step 20) is less than N_{N}, it is incremented by one unit, by calculating C_{N}=C_{N}+1. In a step 32, the value of the counter C_{N} is then compared with the value N_{N}. If C_{N}=N_{N} we go to step 33. Otherwise, we return to step 21 (FIG. 2a) to produce a new sample Sn of the signal S(t). In step 33, the mean of the N_{N} values P_{N}n of the N-1-th series of value of the mean power of the signal S(t) which are available in the register 104_{N} is calculated. To do this, the calculation P_{N}n=(ΣP_{N-1}n)/N_{N} is performed. It will be noted that, in step 33, the counter C_{N} is not initialized. This reflects the fact that the mean computed in step 33 is a sliding average over the N_{N}-tuple of the last N_{N} successive values of the N-1-th series of value P_{N-1}n of the mean power of the signal S(t). Stated otherwise, as soon as the counter C_{N} has reached the value N_{N} the calculation step 33 is performed after each iteration of the storage step 31. Conversely, the calculation step 28 is performed every Nᵢ iterations of the storage step 26, for every i lying between 2 and N-1.

Represented in FIG. 3 is the simplified diagram of a radiofrequency receiver incorporating a device according to the invention. In this figure, only frequency transposition stage and an amplification stage are detailed. The receiver comprises a reception antenna 10 linked to the input of a radiofrequency amplifier 11 which outputs a radiofrequency signal RF, for example phase-modulated or amplitude-modulated. The RF signal is carried to a first input of a mixer 12. A second input of the mixer 12 receives a signal at a frequency f_{LO} which is lower than the frequency of the RF signal, delivered by a local oscillator 13. The mixer 12 outputs an IF signal which corresponds to the RF signal transposed to the intermediate frequency f_{LO}. The IF signal is filtered by means of a filter 14. The output of the filter 14 is linked to the input of a variable-gain amplifier 15 whose output delivers the signal S(t). The receiver comprises a device 16 for measuring the power of the signal S(t) such as described hereinabove with regard to FIG. 1. The device 16 delivers the series of values Pn and P₁n to P_{N}n. In one example these values are provided at the input of a selection module 17 which, as a function of a selection signal SEL, delivers one of the series of values Pn and P₁n to P_{N}n on a control input of an automatic gain control module 18, the output of which controls a gain control input of the variable-gain amplifier 15. In one example, the series of values Pn and P₁n to P₂n are also transmitted to the downstream part 19 of the radiofrequency receiver, which here is represented overall by a. box. This downstream part 19 comprises in particular the means of demodulation and of decoding of the signal S(t).

1. A method of measuring the power of an electric signal (S) comprising the steps consisting in:
a) producing a series of successive samples (Sn) of the signal (S);
b) producing a series of successive values (Pn) of the instantaneous power of the signal (S), from the values of the series of successive samples (Sn) of the signal (S);
c) producing N series of successive values of the mean power of the signal (S) over respectively N time windows of respective increasing widths, where N is an integer such that N≧2, from the values of the series of successive values (Pn) of the instantaneous power of the signal (S).

2. The method as claimed in claim 1, in which in step c) , the values of a first series of values (P₁n) of the mean power of the signal (S) are obtained directly from the values of the series of successive values (Pn) of the instantaneous power of the signal (S), while the values of a j-th series of values (Pⱼn) of the mean power of the signal (S) are obtained from the successive values of the j-1-th series of values (Pⱼ₋₁n) of the mean power of the signal (S), where j is an index such that 2≦j≦N.

3. The method as claimed in claim 2, in which the values of the first series of values (P₁n) of the mean power of the signal (S) are obtained successively by averaging over successive N1-tuples of successive values of the series of values (Pn) of the instantaneous power of the signal (S) where N1 is an integer such that N1≧2.

4. The method as claimed in claim 2 or claim 3, in which for the values of j such that 2≦j≦N, the values of a j-th series of values (Pⱼn) of the mean power of the signal (S) are obtained successively by averaging over successive Nⱼ-tuples of successive values of the j-1-th series of values (Pⱼ₋₁n) of the mean power of the signal (S) where Nⱼ is an integer such that Nⱼ≧2.

5. The method as claimed in one of claims 2 to 4, in which the values of the N-th series of values (P_{N}n) of the mean power of the signal (S) are obtained successively by taking a sliding average over the N_{N}-tuple of the last N_{N} successive values of the N-1-th series of values (P_{N-1}n) of the mean power of the signal (S).

6. The method as claimed in claims 3 to 5, in which the mean is an arithmetic mean.

7. The method as claimed in one of claims 2 to 6, in which, for certain at least of the values of the index j lying between 1 and N, there exists an integer kⱼ such that Nⱼ=2^{k}ⱼ.

8. A device for measuring the power of an electric signal (S) comprising:
a) means (100, 101) for producing a series of successive samples (Sn) of the signal (S);
b), means (102) for producing a series of successive values (Pn) of. the instantaneous power of the signal (S), each of these values being obtained from the value of a respective sample of the series of successive samples (Sn) of the signal (S);
c) means (103₁-103_{N}) for producing N series of successive values of the mean power of the signal (S) over respectively N time windows of respective increasing widths, where N is an integer such that N≧2, from the values of the series of successive values (Pn) of the instantaneous power of the signal (S).

9. The device as claimed in claim 8, in which the means for producing N series of successive values of the mean power of the signal (S) comprise means (103₁) for producing the first series of values (P₁n) of the mean power of the signal (S) directly from the values of the series of successive values (Pn) of the instantaneous power of the signal (S), and means (103₂-103_{N}) for producing the values of a j-th series of values (Pⱼn) of the mean power of the signal (S) from the successive values of the j-1-th series of values (Pⱼ₋₁n) of the mean power of the signal (S), where j is an index such that 2≦j≦N.

10. The device as claimed in claim 9, in which the means (103₁) for producing the values of the first series of values (P₁n) of the mean power of the signal (S) operate successively by averaging over successive N1-tuples of successive values of the series of values (Pn) of the instantaneous power of the signal (S) where N1 is an integer such that N1≧2.

11. The device as claimed in claim 9 or claim 10, in which the means (103₁-103_{N}) for producing the values of a j-th series of values (Pⱼn) of the mean power of the signal (S) for the values of j such that 2≦j≦N, operate successively by averaging over successive Nⱼ-tuples of successive values of the j-1-th series of values (Pⱼ₋₁n) of the mean power of the signal (S) where Nⱼ is an integer such that Nⱼ>2.

12. The device as claimed in claim 11, in which the means (103₂-103_{N}) for producing the values of a j-th series of values (Pⱼn) of the mean power of the signal (S) for the values of j such that 2≦j<N, comprise a shift register of length Nⱼ for storing Nⱼ successive values of the j-1-th series of values (Pⱼ₋₁n) of the mean power of the signal (S).

13. The device as claimed in one of claims 9 to 12, in which the means (103_{N}) for producing the values of the N-th series of values (P_{N}n) of the mean power of the signal (S) operate successively by taking a sliding average over the N_{N}-tuple of the last N_{N} successive values of the N-1-th series of values (P_{N-1}n) of the mean power of the signal (S).

14. The device as claimed in claim 10 to 13, in which the mean is an arithmetic mean.

15. The device as claimed in one of claims 8 to 14, in which, for certain at least of the values of the index j lying between 1 and N, there exists an integer kⱼ such that Nⱼ=2^{k}ⱼ.

16. Radiofrequency radiocommunication receiver incorporating a device as claimed in any one of claims 8 to 15.
